(19) United States
(12) Patent Application Publication
(10) Pub. No.: US 2008/0042122 A1
(43) Pub. Date: Feb. 21, 2008

(54) Semiconductor light emitting element, method of manufacturing the same and semiconductor light emitting device

(75) Inventors: Nobuaki Hatori, Kanagawa (JP); Tsuyoshi Yamamoto, Kawasaki (JP); Yoshiaki Nakata, Kanagawa (JP); Yasuhiko Arakawa, Kanagawa (JP)

Correspondence Address: KRATZ, QUINTOS & HANSON, LLP, 1420 K Street, N.W., Suite 400, WASHINGTON, DC, 20005, US

(73) Assignees: FUJITSU LIMITED, Kawasaki (JP); THE UNIVERSITY OF TOKYO, Tokyo (JP)

(21) Appl. No.: 11/889,364

(22) Filed: Aug. 13, 2007

(30) Foreign Application Priority Data
Aug. 15, 2006 (JP) 2006-221668

(51) Int. Cl. H01L 33/00

(52) U.S. Cl. 257/13; 438/47; 257/E33.005

(57) ABSTRACT

A semiconductor light emitting element improving luminous efficiency has: a semiconductor substrate, an N-type cladding layer formed over the substrate; a barrier layer formed over the cladding layer; a quantum dot layer formed over the barrier layer, the quantum dot layer including quantum dots having a band gap smaller than that of the barrier layer and a buried layer having a band gap larger than that of the quantum dots, the buried layer covering a sidewall of the quantum dots; a P-type semiconductor layer formed over the quantum dot layer, the semiconductor layer having a band gap smaller than that of the barrier layer; a barrier layer formed over the P-type semiconductor layer, the barrier layer having a band gap larger than those of the quantum dots and of the semiconductor layer; and a p-type cladding layer formed over the barrier layer. Therefore, holes generated in the P-type semiconductor layer are prevented from flowing into the barrier layer and the buried layer.

### CROSS-REFERENCE TO RELATED APPLICATIONS

This application is based upon and claims the benefits of priority from the prior Japanese Patent Application No. 2006-221668 filed on Aug. 15, 2006, the entire contents of which are incorporated herein by reference.

### BACKGROUND OF THE INVENTION

1. Field of the Invention

The present invention relates to a semiconductor light emitting element, to a method of manufacturing the same and to a semiconductor light emitting device. More specifically, the present invention relates to a semiconductor light emitting element having quantum dots, to a method of manufacturing the same and to a semiconductor light emitting device.

2. Description of the Related Art

A P-type quantum dot semiconductor laser has a semiconductor light emitting element formed by sandwiching between two cladding layers a quantum dot active layer having a barrier layer, a wetting layer, quantum dots, a strain relaxation layer covering the quantum dots, and a barrier layer partially doped with p-type impurities (see, e.g., Electronics Letters 2002, Vol. 38, no. 14, pp. 712 to 713), or by sandwiching between two cladding layers a quantum dot active layer having a barrier layer, a wetting layer, quantum dots and a p-type barrier layer covering the quantum dots (see, e.g., Japanese Unexamined Patent Application Publication No. 2003-023219).

This P-type quantum dot semiconductor laser has the following excellent features. As compared with a conventional non-doped quantum dot semiconductor laser, a modulation characteristic can be improved because a differential gain increases, and temperature dependence of laser can be largely suppressed. Therefore, this semiconductor light emitting element has been developed as a light source for metro/access optical fiber communication.

However, the semiconductor light emitting element having quantum dots has the following problems.

Here, the problems will be described below by giving two conventional examples.

As for a first conventional example, FIG. 12 is a schematic cross-sectional view of an essential part of a conventional semiconductor light emitting element, FIG. 13 is a schematic view illustrating a band diagram of a cross-sectional, structure taken along the line X-X′ in FIG. 12, and FIG. 14 is a schematic view illustrating a band diagram of a cross-sectional structure taken along the line Y-Y′ in FIG. 12.

A semiconductor light emitting element 101 shown in FIG. 12 has a structure in which an N-type aluminum gallium arsenic (N—AlGaAs) cladding layer 102, a gallium arsenic (GaAs) barrier layer 103, a wetting layer 104, a quantum dot layer 105 having indium arsenic (InAs) quantum dots 105a and an indium gallium arsenic (InGaAs) strain relaxation layer 106 covering the InAs quantum dots 105a, a GaAs barrier layer 108 having a P-type GaAs barrier layer 107 partially doped with P-type impurities, and a P-type AlGaAs cladding layer 109 are sequentially formed over a substrate (not shown). FIGS. 13 and 14 are schematic views illustrating band diagrams of cross-sectional structures taken along the dashed lines X-X′ and Y-Y′ in FIG. 12.

According to FIGS. 13 and 14, any of the P-type GaAs barrier layer 107 and the GaAs barrier layer 108 around the layer 107 are made of GaAs. Therefore, holes 107a generated in the P-type GaAs barrier layer 107 have no potential barrier. Accordingly, most of the holes 107a generated in the layer 107 remain in the GaAs barrier layer 108 and are not efficiently trapped in the InAs quantum dots 105a. As a result, injection efficiency of the holes 107a into the InAs quantum dots 105a is reduced. Therefore, when a large amount of P-type impurities are doped to obtain the sufficient injection efficiency of the holes 107a into the InAs quantum dots 105a, crystallinity of the P-type GaAs barrier layer 107 decreases and luminous efficiency decreases.

As for a second conventional example, FIG. 15 is a schematic cross-sectional view of an essential part of a conventional semiconductor light emitting element, FIG. 16 is a schematic view illustrating a band diagram of a cross-sectional structure taken along the dashed line X-X′ in FIG. 15, and FIG. 17 is a schematic view illustrating a band diagram of a cross-sectional structure taken along the dashed line Y-Y′ in FIG. 15.

FIG. 15 shows a structure in which different from the first conventional example, InAs quantum dots 205a are completely buried in a P-type GaAs barrier layer 207. More specifically, a semiconductor light emitting element 201 shown in FIG. 15 has a structure in which an N-type aluminum gallium arsenic (N—AlGaAs) cladding layer 202, a GaAs barrier layer 203, a wetting layer 204, a quantum dot layer 205 having InAs quantum dots 205a and a P-type GaAs barrier layer 207 covering the InAs quantum dots 205a, and a P-type AlGaAs cladding layer 209 are sequentially formed over a substrate (not shown). FIGS. 16 and 17 are schematic views illustrating band diagrams of the cross-sectional structures taken along the dashed lines X-X′ and Y-Y′ in FIG. 15.

According to FIGS. 16 and 17, similarly to the first conventional example, most of the holes 207a generated in the P—GaAs barrier layer 207 remain in the P—GaAs barrier layer 207 and are not efficiently trapped in the InAs quantum dots 205a. As a result, injection efficiency of the holes 207a into the InAs quantum dots 205a is reduced. Therefore, when a large amount of P-type impurities are doped to obtain the sufficient injection efficiency of the holes 207a into the InAs quantum dots 205a, crystallinity of the P-type GaAs barrier layer 207 decreases and luminous efficiency decreases. Further, since sidewalls of the InAs quantum dots 205a are buried in the P—GaAs barrier layer 207, the P-type impurities in the P—GaAs barrier layer 207 come in contact with the sidewalls of the InAs quantum dots 205a under the condition that shapes of the InAs quantum dots 205a are not fixed. As a result, crystallinity of the InAs quantum dots 205a decreases.

It has a problem of the present invention to provide a semiconductor light emitting element capable of improving luminous efficiency. It has another problem of the present invention to provide a method of manufacturing the semiconductor light emitting element. It has yet another problem of the present invention to provide a semiconductor light emitting device.

### SUMMARY OF THE INVENTION

To accomplish the above objects, according to one aspect of the present invention, there is provided a semiconductor light emitting element. This semiconductor light emitting element has: a semiconductor substrate; a first conductivity-type cladding layer formed over the semiconductor substrate; a first barrier layer formed over the first conductivity-type cladding layer; a quantum dot layer formed over the first barrier layer, the quantum dot layer including the quantum dots having a band gap smaller than that of the first barrier layer and a buried layer having a band gap larger than that of the quantum dots, the buried layer covering a sidewall of the quantum dots; a P-type semiconductor layer formed over the quantum dot layer, the P-type semiconductor layer having a band gap smaller than that of the first barrier layer; a second barrier layer formed over the P-type semiconductor layer, the second barrier layer having a band gap larger than those of the quantum dots and of the P-type semiconductor layer; and a second conductivity-type cladding layer formed over the second barrier layer.

According to another aspect of the present invention, there is provided a method of manufacturing a semiconductor light emitting element having quantum dots. This method has the steps of: forming a first conductivity-type cladding layer over the semiconductor substrate; forming a first barrier layer over the first conductivity-type cladding layer; forming a quantum dot layer over the first barrier layer, the quantum dot layer including the quantum dots having a band gap smaller than that of the first barrier layer and a buried layer having a band gap larger than that of the quantum dots, the buried layer covering a sidewall of the quantum dots; forming a P-type semiconductor layer over the quantum dot layer, the P-type semiconductor layer having a band gap smaller than that of the first barrier layer; forming a second barrier layer over the P-type semiconductor layer, the second barrier layer having a band gap larger than those of the quantum dots and of the P-type semiconductor layer; and forming a second conductivity-type cladding layer over the second barrier layer.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a schematic cross-sectional view of an essential part of a semiconductor light emitting element.

FIG. 2 is a schematic cross-sectional view of an essential part of a semiconductor light emitting element according to the first embodiment.

FIG. 3 is a schematic view illustrating a band diagram of a cross-sectional structure taken along the line X-X′ in FIG. 2.

FIG. 4 is a schematic view illustrating a band diagram of a cross-sectional structure taken along the line Y-Y′ in FIG. 2.

FIG. 5 is a schematic cross-sectional view of an essential part of a semiconductor light emitting element according to a second embodiment.

FIG. 6 is a schematic oblique view of a semiconductor light emitting laser device according to the second embodiment.

FIG. 7 is a schematic cross-sectional view of an essential part of a semiconductor light emitting element according to a third embodiment.

FIG. 8 is a schematic view illustrating a band diagram of a cross-sectional structure taken along the dashed line Y-Y′ in FIG. 7.

FIG. 9 is a schematic oblique view of a semiconductor light emitting laser device according to a fourth embodiment.

FIG. 10 is a schematic oblique view of a semiconductor light emitting laser device according to a fifth embodiment.

FIG. 11 is a schematic oblique view of a semiconductor light emitting laser device according to a sixth embodiment.

FIG. 12 is a schematic cross-sectional view of an essential part of a conventional semiconductor light emitting element (part 1).

FIG. 13 is a schematic view illustrating a band diagram of a cross-sectional structure taken along the dashed line X-X′ in FIG. 12.

FIG. 14 is a schematic view illustrating a band diagram of a cross-sectional structure taken along the dashed line Y-Y′ in FIG. 12.

FIG. 15 is a schematic cross-sectional view of an essential part of a conventional semiconductor light emitting element (part 2).

FIG. 16 is a schematic view illustrating a band diagram of a cross-sectional structure taken along the dashed line X-X′ in FIG. 15.

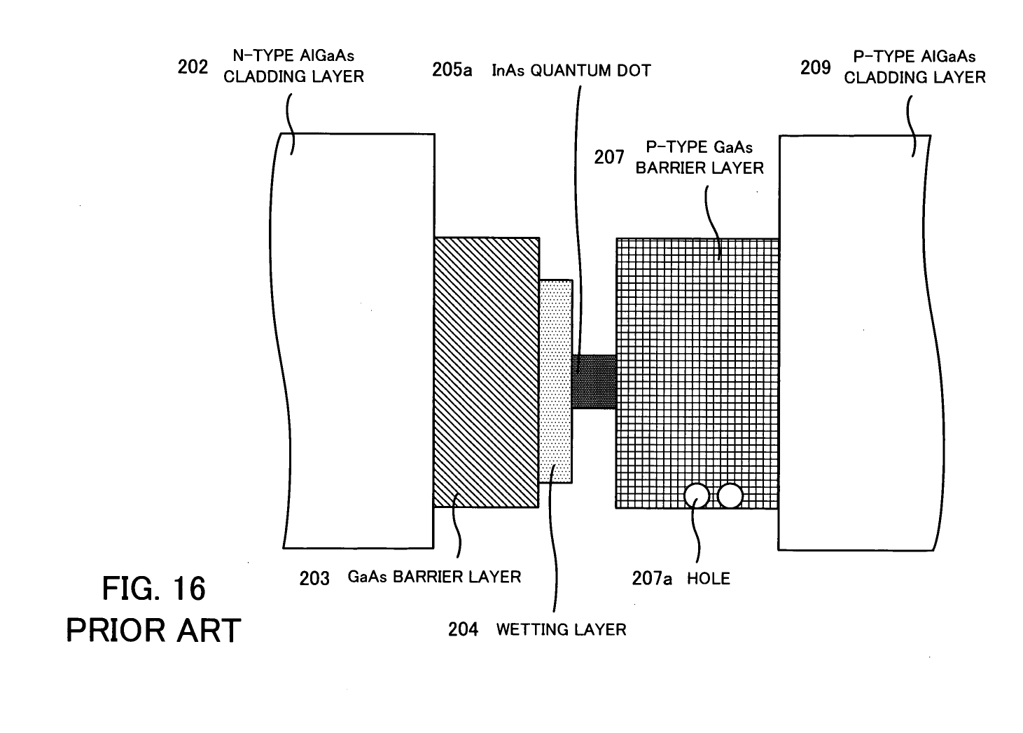

FIG. 17 is a schematic view illustrating a band diagram of a cross-sectional structure taken along the dashed line Y-Y′ in FIG. 15.

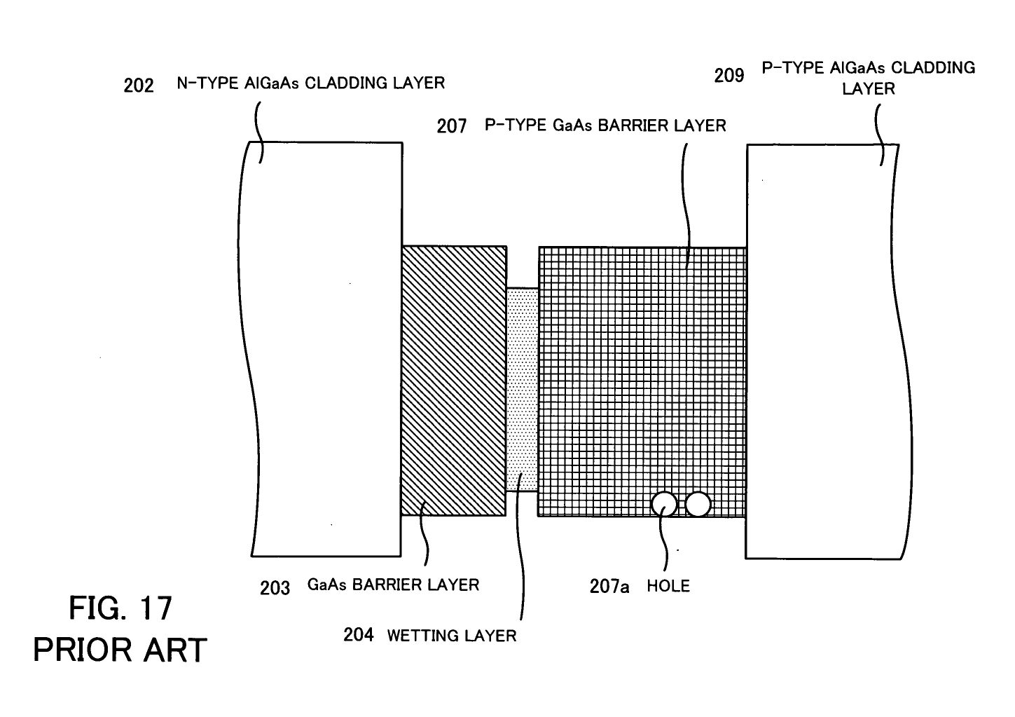

### DESCRIPTION OF THE PREFERRED EMBODIMENTS

Preferred embodiments of the present invention will be described in detail below with reference to the accompanying drawings, wherein like reference numerals refer to like elements throughout.

First, an outline of the operating principle of the present invention will be described.

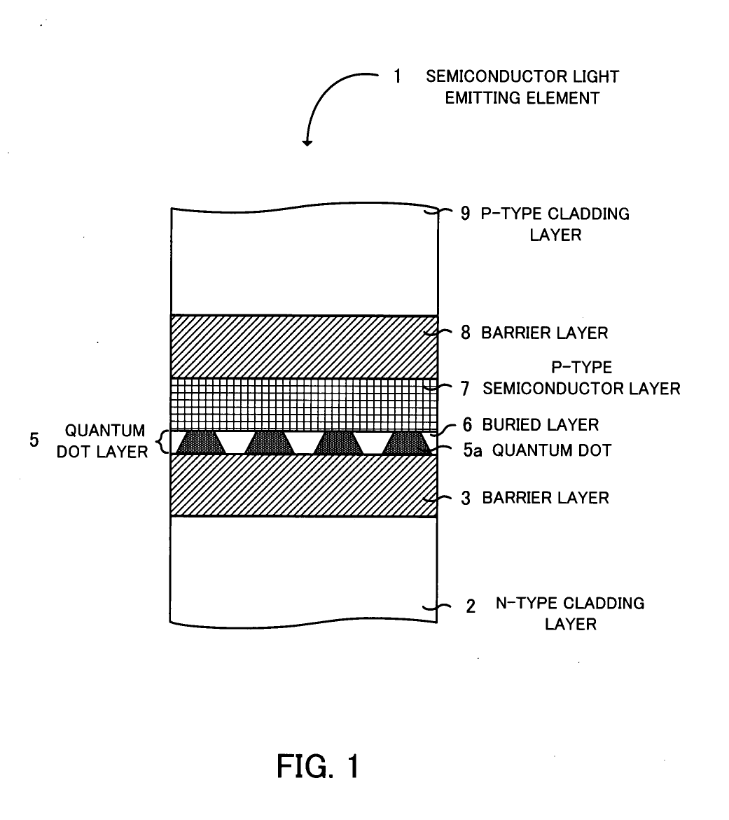

FIG. 1 is a schematic cross-sectional view of an essential part of a semiconductor light emitting element.

A semiconductor light emitting element 1 has a structure in which an N-type cladding layer 2; a barrier layer 3; a quantum dot layer 5 including quantum dots 5a having a band gap smaller than those of the barrier layers 3 and 8 and a buried layer 6 having a band gap larger than those of the quantum dots 5a, the buried layer 6 covering a sidewall of the quantum dots 5a; a P-type semiconductor layer 7 having a band gap smaller than those of the barrier layers 3 and 8; a barrier layer 8; and a P-type cladding layer 9 are sequentially formed over a semiconductor substrate (not shown).

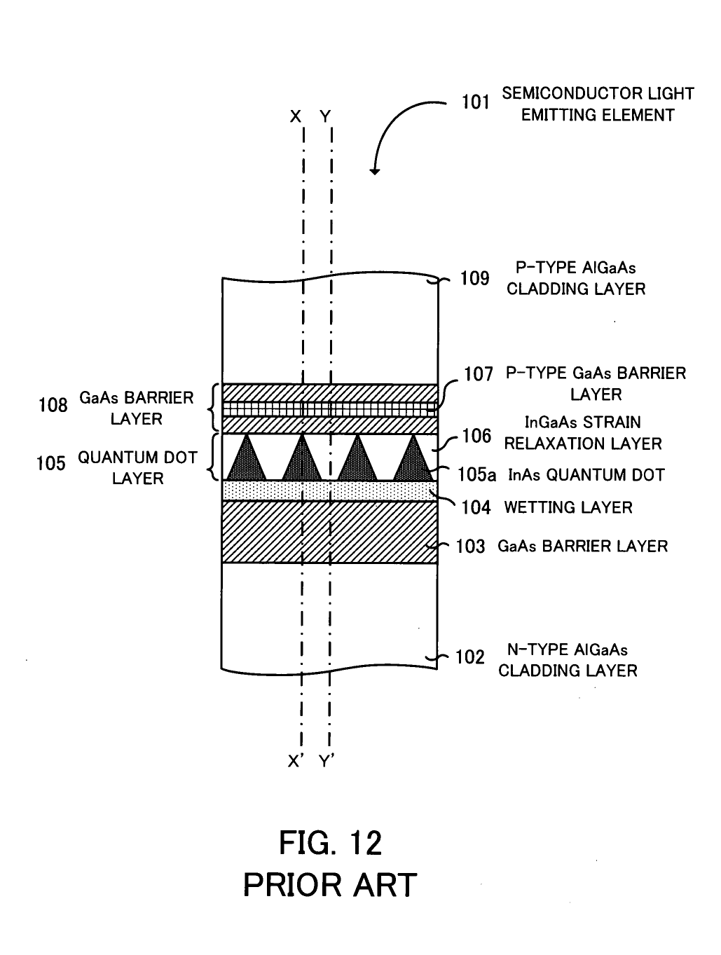

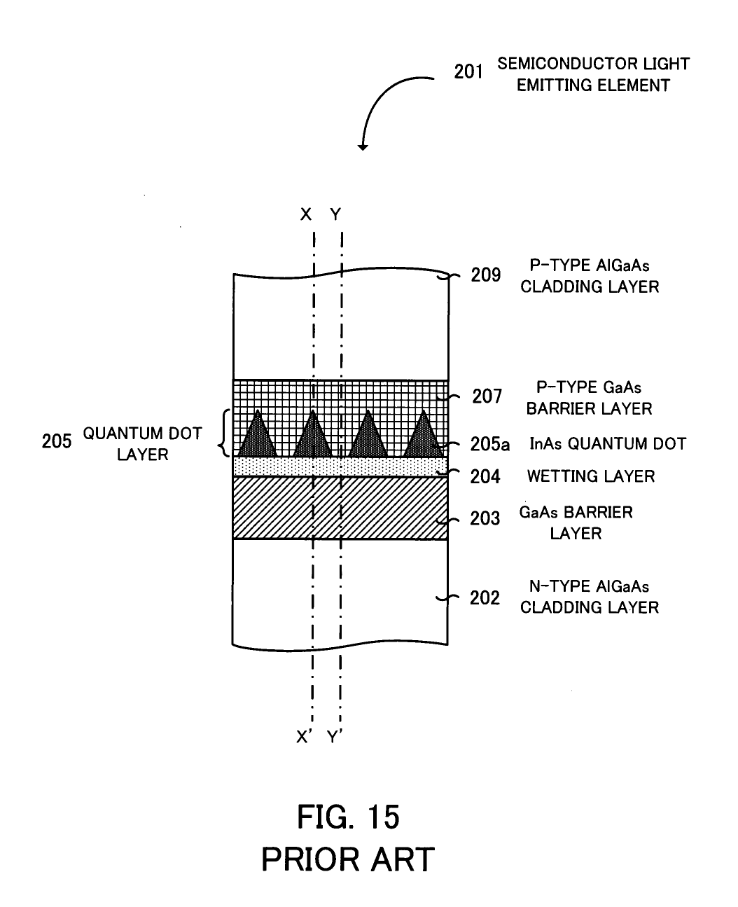

According to this structure, the band gap of the P-type semiconductor layer 7 is made smaller than those of the buried layer 6 and the barrier layers 3 and 8. Therefore, holes generated in the P-type semiconductor layer 7 are effectively infected into the quantum dots 5a without flowing into the buried layer 6 and the barrier layer 8. Accordingly, as compared with conventional semiconductor light emitting elements 101 and 201 as shown in FIGS. 12 and 15, the doping amount of the P-type impurities can be reduced, so that increase in the threshold current due to recombination can be suppressed.

In addition, the buried layer 6 covering the sidewall of the quantum dots 5a has no impurities, and doping of P-type impurities into the P-type semiconductor layer 7 is performed after the formation of the quantum dots 5a. That is, the P-type impurities are not in contact with the sidewall of the quantum dots 5a during the formation of the quantum dots 5a. Accordingly, the influence of the P-type impurities on the quantum dots 5a can be suppressed, so that the quality of the quantum dots 5a can be maintained.

Thus, the semiconductor light emitting element 1 has a structure in which an N-type cladding layer 2; a barrier layer 3; a quantum dot layer 5 including quantum dots 5a having a band gap smaller than those of the barrier layers 3 and 8 and a buried layer 6 having a band gap larger than that of the quantum dots 5a, the buried layer 6 covering a sidewall of the quantum dots 5a; a P-type semiconductor layer 7 having a band gap smaller than those of the barrier layers 3 and 8; a barrier layer 8; and a P-type cladding layer 9 are sequentially formed over a semiconductor substrate. As a result, the quality of the quantum dots 5a is maintained as well as the injection efficiency of the holes into the quantum dots 5a is improved, so that the luminous efficiency can be improved.

When a lattice constant of the buried layer 6 is larger than that of the substrate, strain occurs in the buried layer 6, so that the band gap of the quantum dots 5a can be changed by this strain. The buried layer 6 at this time can be referred to as a strain relaxation layer.

Next, a first embodiment will be described.

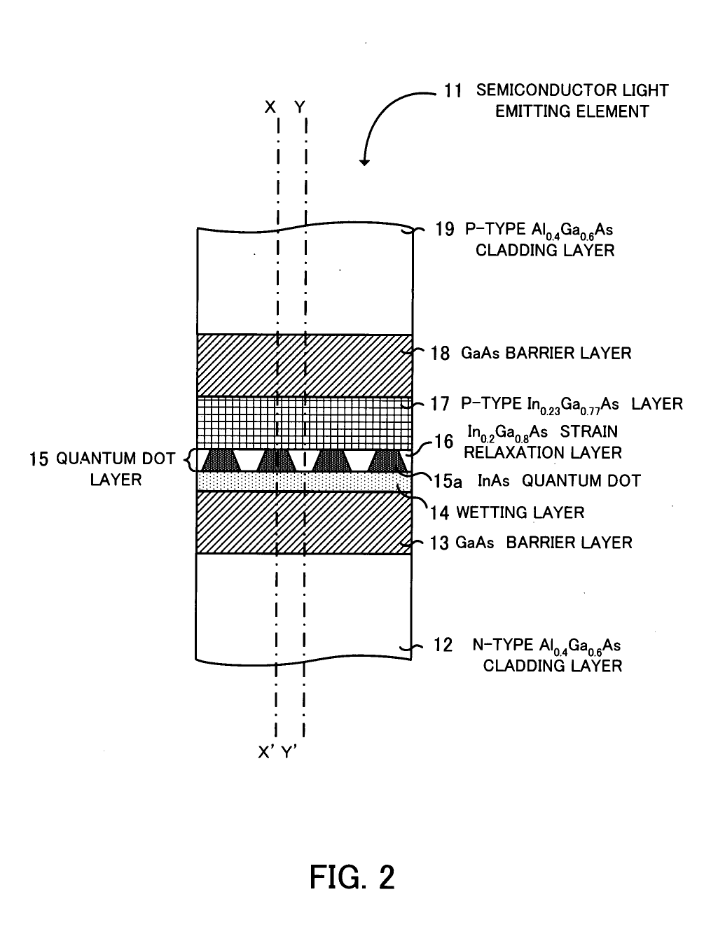

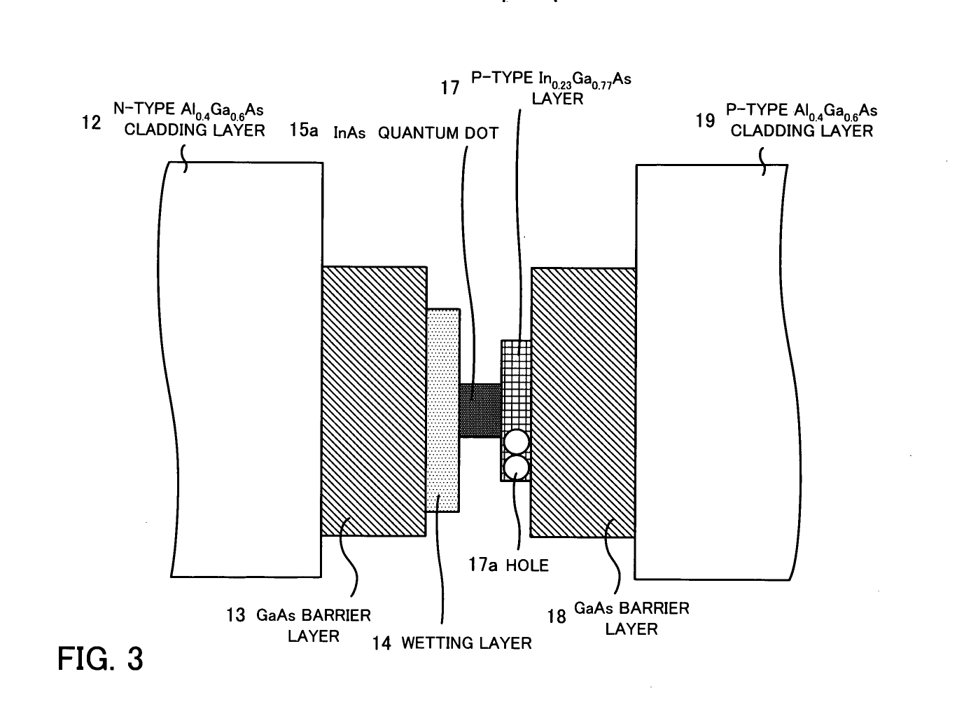

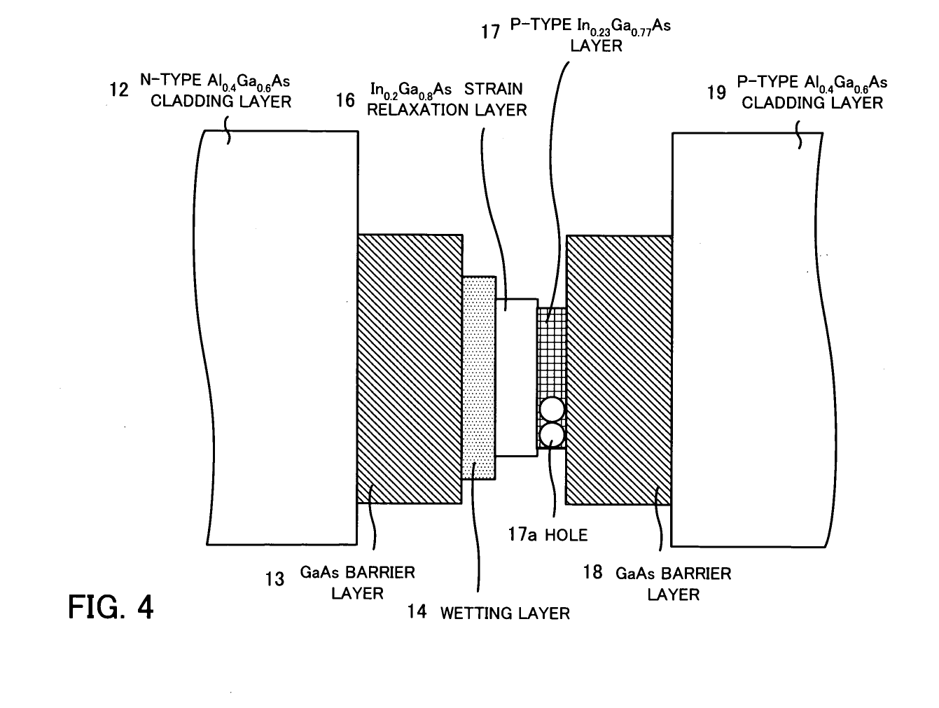

FIG. 2 is a schematic cross-sectional view of an essential part of a semiconductor light emitting element according to the first embodiment. FIG. 3 is a schematic view illustrating a band diagram of a cross-sectional structure taken along the dashed line X-X′ in FIG. 2. FIG. 4 is a schematic view illustrating a band diagram of a cross-sectional structure taken along the dashed line Y-Y′ in FIG. 2.

A semiconductor light emitting element 11 shown in FIG. 2 has a structure in which an N-type Al_{0.4}Ga_{0.6}As cladding layer 12, a GaAs barrier layer 13, a wetting layer 14, a quantum dot layer 15 having InAs quantum dots 15a and an In_{0.2}Ga_{0.8}As strain relaxation layer 16 covering a sidewall of the InAs quantum dots 15a, a P-type In_{0.23}Ga_{0.77}As layer 17, a GaAs barrier layer 18 and a P-type Al_{0.4}Ga_{0.6}As cladding layer 19 are sequentially formed over an N-type GaAs (001) substrate (not shown). Such a semiconductor light emitting element 11 is formed, for example, as follows.

First, the N-type Al_{0.4}Ga_{0.6}As cladding layer 12 (thickness: about 1.4 μm) is formed by a Molecular Beam Epitaxy (MBE) over the N-type GaAs (001) substrate (not shown).

Then, the GaAs barrier layer 13 (thickness: about 33 nm) is formed by the MBE over the N-type Al_{0.4}Ga_{0.6}As cladding layer 12.

Then, the InAs quantum dots 15a are formed to have a surface density of about 4×10¹⁰ cm⁻² by a self-assemble method over the GaAs barrier layer 13. At this time, the wetting layer 14 is also formed with the InAs quantum dots 15a.

Then, the In_{0.2}Ga_{0.8}As strain relaxation layer 16 having no impurities is formed by the MBE to cover the sidewalls of the InAs quantum dots 15a. At this time, a thickness of the In_{0.2}Ga_{0.8}As strain relaxation layer 16 is made smaller than a height of the InAs quantum dots 15a.

Then, the top of the InAs quantum dots 15a is reevaporated using a flushing method while raising a temperature within a furnace for performing the MBE. Thereby, the height of the InAs quantum dots 15a is made equal to a thickness of the In_{0.2}Ga_{0.8}As strain relaxation layer 16. Through this step, the quantum dot layer 15 including the InAs quantum dots 15a and the In_{0.2}Ga_{0.8}As strain relaxation layer 16 covering the sidewall of the InAs quantum dots 15a is formed.

Then, the P-type In_{0.23}Ga_{0.77}As layer 17 (thickness: about 10 nm) having a P-type impurity concentration of about 5×10¹⁷ cm⁻³ is formed by the MBE over the quantum dot layer 15.

Then, the GaAs barrier layer 18 (thickness: about 23 nm) is formed by the MBE over the p-type In_{0.23}Ga_{0.77}As layer 17.

Then, the p-type Al_{0.4}Ga_{0.6}As cladding layer 19 is formed by the MBE over the GaAs barrier layer 18.

Thus, the semiconductor light emitting element 11 is manufactured.

In the first embodiment, the In_{0.2}Ga_{0.8}As strain relaxation layer 16 covering the sidewall of the InAs quantum dots 15a has no impurities, and the p-type In_{0.23}Ga_{0.77}As layer 17 over the quantum dot layer 15 is formed after the formation of the InAs quantum dots 15a. That is, the sidewall of the InAs quantum dots 15a are not in contact with impurities. Accordingly, it becomes possible to form the InAs quantum dots 15a whose crystallinity is prevented from decreasing and whose quality is maintained.

On the other hand, the holes 17a generated in the P-type In_{0.23}Ga_{0.77}As layer 17 as shown in FIG. 3 are prevented from flowing into the GaAs barrier layer 18 having a large band gap. As a result, most of the holes 17a are caused to flow into the InAs quantum dots 15a. Further, the holes 17a generated in the p-type In_{0.23}Ga_{0.77}As layer 17 as shown in FIG. 4 are prevented from flowing into the In_{0.2}Ga_{0.8}As strain relaxation layer 16 and GaAs barrier layer 18 having a band gap larger than that of the hole 17a. As a result, most of the holes 17a are caused to flow into the InAs quantum dots 15a. Thus, by the structure of the first embodiment, the holes 17a generated in the P-type In_{0.23}Ga_{0.77}As layer 17 are efficiently injected into the InAs quantum dots 15a.

Next, the amount of the holes 17a injected into the InAs quantum dots 15a will be described below.

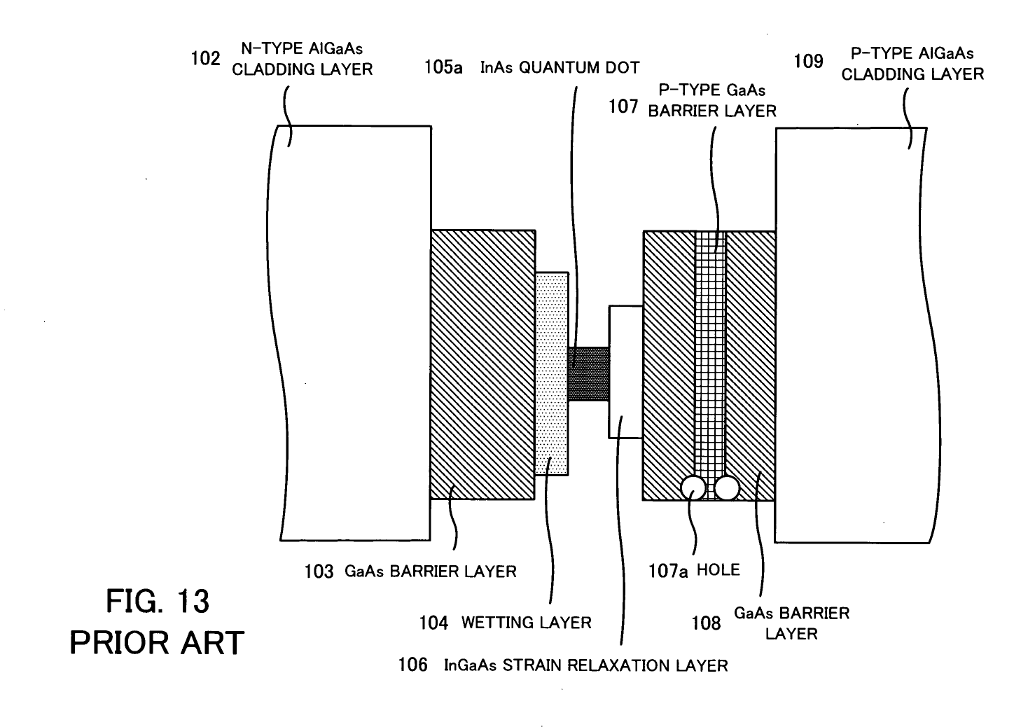

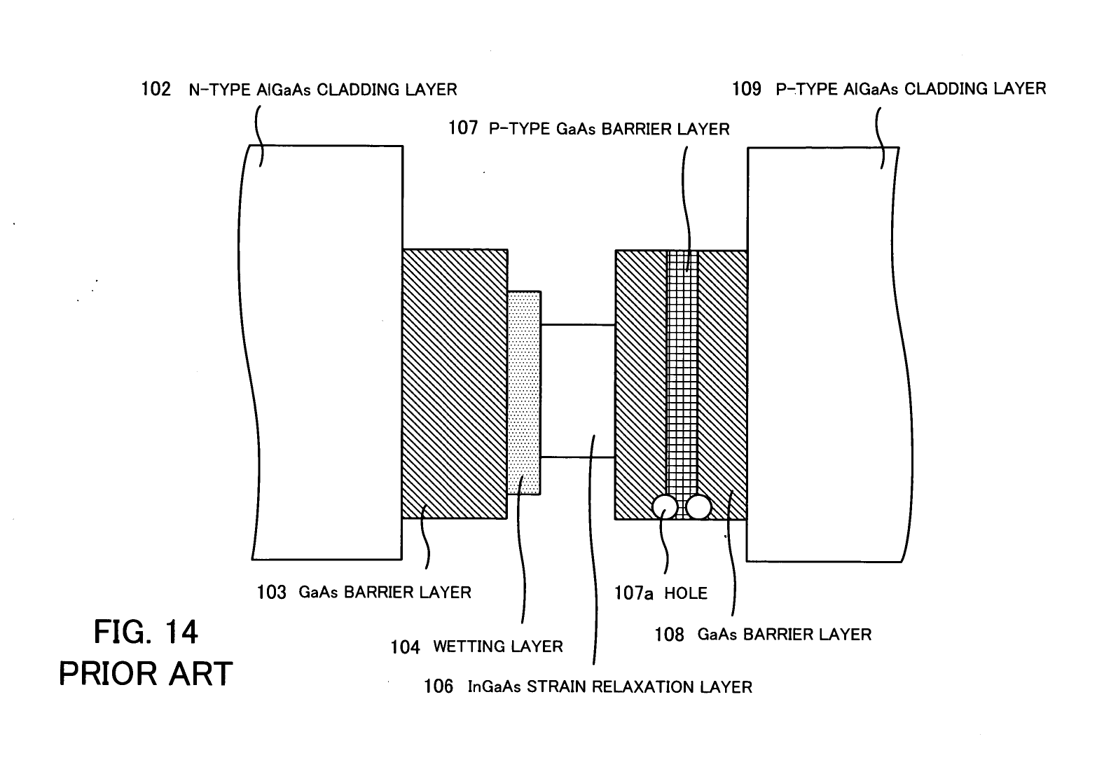

In the first embodiment, the surface density of the holes 17a generated in the P-type In_{0.23}Ga_{0.77}As layer 17 (thickness: about 10 nm) having a P-type impurity concentration of about 5×10¹⁷ cm⁻³ is about 5×10¹¹ cm⁻². Further, the surface density of the InAs quantum dots 15a is about 4×10¹⁰ cm⁻². Accordingly, the number of holes injected into the single InAs quantum dot 15a is equal to about 12. On the other hand, in the semiconductor light emitting element 101 as the conventional example shown in FIG. 12, the GaAs barrier layer 108 (thickness: about 33 nm) includes the P-type GaAs barrier layer 107 (thickness: about 10 nm) having a p-type impurity concentration of about 5×10¹⁷ cm⁻³. As a result, the holes 107a are caused to spread over the GaAs barrier layer 108 and the surface density of the holes 107a is effectively about 1.5×10¹¹ cm⁻² Accordingly, the number of holes injected into the single InAs quantum dot 105a is equal to about 3.7. However, in FIG. 12, since the sidewall of the InAs quantum dots 105a are covered with an InGaAs strain relaxation layer 106 having a band gap smaller than that of the GaAs barrier layer 108, the holes 107a remaining in the GaAs barrier layer 108 are present as shown in FIGS. 13 and 14 and the number of holes injected into the single InAs quantum dot 105a is reduced to less than 3.7.

Thus, in the first embodiment, the quality of the quantum dots can be maintained as well as the crystallinity thereof can be maintained by the doping of p-type impurities in an amount smaller than that in the conventional example, and holes can be efficiently injected into the quantum dots. As a result, an ineffective current is reduced, so that luminous efficiency can be improved.

In the first embodiment, a layer formed using the MBE can also be formed by appropriately using a conventionally known crystal growth method.

In the first embodiment, materials are selected such that a lattice constant of the In_{0.2}Ga_{0.8}As strain relaxation layer 16 is larger than that of the N—GaAs (001) substrate (not shown). The reason is as follows. That is, when the lattice constant of the In_{0.2}Ga_{0.8}As strain relaxation layer 16 is made larger than that of the N—GaAs (001) substrate (not shown), a strain occurs in the In_{0.2}Ga_{0.8}As strain relaxation layer 16, so that the band gap of the InAs quantum dots 15a can be changed by this strain.

In the first embodiment, description is made on a structure in the case where P-type impurities are doped throughout the whole thickness of 10 nm of the P-type In_{0.23}Ga_{0.77}As layer 17 formed over the quantum dot layer 15. Even if the P-type In_{0.23}Ga_{0.77}As layer 17 is formed, for example, by the combination of layered structures including a 5-nm-thick lower In_{0.23}Ga_{0.77}As layer and a 5-nm-thick upper P—In_{0.23}Ga_{0.77}As layer with a thickness of 5 nm, the same effect as that of the first embodiment can be obtained. In this case, however, the doped impurity concentration must be increased in order to obtain the same P-type impurity concentration effect as in the case where the P-type impurities are doped throughout the whole thickness of 10 nm. However, since the top of the InAs quantum dots 15a is not in direct contact with the p-type impurities, the influence of the p-type impurities on the InAs quantum dots 15a is suppressed, so that the quality of the InAs quantum dots 15a can be maintained. Further, even if a thickness of the P-type In_{0.23}Ga_{0.77}As layer 17 is reduced to form a P-type delta-doped structure, the same effect as that of the first embodiment can be obtained.

In the first embodiment, description is made on a structure in the case where a stoichiometric ratio of the indium composition in the P-type In_{0.23}Ga_{0.77}As layer 17 is set to 0.23. Also when the stoichiometric ratio of the indium composition in the P-type In_{0.23}Ga_{0.77}As layer 17 is changed from 0.23 to 0.26 toward the InAs quantum dots 15a, the same effect as that of the first embodiment can be obtained. In the P-type In_{0.23}Ga_{0.77}As layer 17, when the stoichiometric ratio of the indium composition is increased, the band gap is reduced. As a result, the number of holes remaining in the P-type In_{0.23}Ga_{0.77}As layer 17 decreases, so that the holes can be efficiently injected into the InAs quantum dots 15a. Further, even if the change of the band gap due to the change of the stoichiometric ratio of the indium composition has a line shape or a form of plural steps, the same effect as that of the first embodiment can be obtained.

In the first embodiment, description is made on a structure in the case where a stoichiometric ratio of the indium composition in the P-type In_{0.23}Ga_{0.77}As layer 17 is set to 0.23 and a stoichiometric ratio of the indium composition in the In_{0.2}Ga_{0.8}As strain relaxation layer 16 is set to 0.2. These stoichiometric ratios of the indium compositions may be the same. Even if the stoichiometric ratios of the indium compositions are made equal, the P-type InGaAs layer 17 has a hole confinement effect because being sandwiched between the GaAs barrier layers 13 and 18.

In the first embodiment, description is made on a structure in the case where the In_{0.2}Ga_{0.8}As strain relaxation layer 16 is used as a strain relaxation layer. Besides InGaAs, for example, when using AlGaAs, the same effect as that of the first embodiment can be obtained.

The structure of the first embodiment may be changed to the following structure. That is, the semiconductor light-emitting element 11 can be formed using an indium phosphorus (InP) substrate for the N-type GaAs (001) substrate (not shown), an aluminum gallium indium arsenic (AlGaInAs) barrier layer or an indium gallium arsenic phosphorus (InGaAsP) barrier layer for the GaAs barrier layers 13 and 18, and a P-type aluminum gallium indium arsenic (P—AlGaInAs) layer or a P-type indium gallium arsenic phosphorus (P—InGaAsP) for the p-type In_{0.23}Ga_{0.77}As layer 17. At this time, when the P—AlGaInAs layer is formed by being lattice-matched to the InP substrate, a strain energy is prevented from being stored in the semiconductor light emitting element 11, so that formation of the laminated structure is made easy.

Next, a second embodiment will be described.

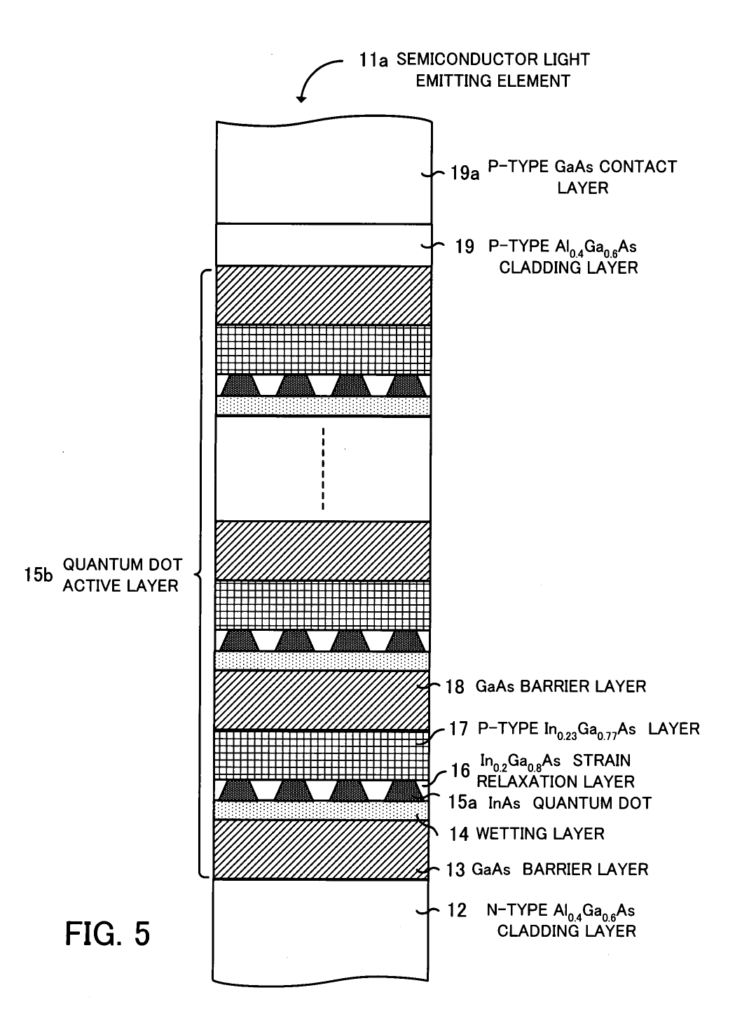

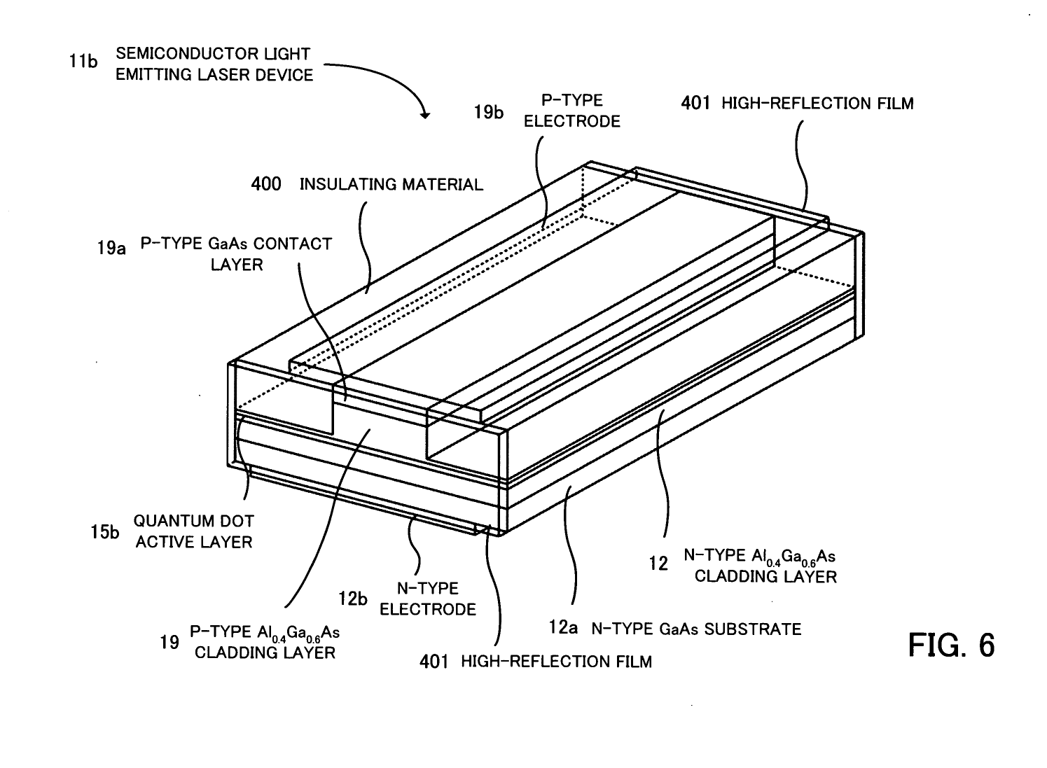

FIG. 5 is a schematic cross-sectional view of an essential part of a semiconductor light emitting element according to the second embodiment. FIG. 6 is a schematic oblique view of a semiconductor light emitting laser device according to the second embodiment.

A semiconductor light emitting element 11a of the second embodiment has a structure in which, in the semiconductor light emitting element 11 of the first embodiment, the wetting layer 14, the quantum dot layer 15, the p-type In_{0.23}Ga_{0.77}As layer 17 and the GaAs barrier layer 18 are alternately laminated plural times over the GaAs barrier layer 13. That is, the semiconductor light emitting element 11a has a quantum dot active layer 15b in which the wetting layer 14, the quantum dot layer 15, the p-type In_{0.23}Ga_{0.77}As layer 17 and the GaAs barrier layer 18 are alternately laminated plural times over the GaAs barrier layer 13. The element 11a and the semiconductor light emitting laser device 11b having the element 11a are formed, for example, as follows.

First, the N-type Al_{0.4}Ga_{0.6}As cladding layer 12 (thickness: about 1.4 μm) is formed by the MBE over the N-type GaAs (001) substrate (not shown).

Then, the GaAs barrier layer 13 (thickness: about 33 nm) is formed by the MBE over the N-type Al_{0.4}Ga_{0.6}As cladding layer 12.

Then, the InAs quantum dots 15a are formed to have a surface density of about 4×10¹⁰ cm⁻² by a self-assemble method over the GaAs barrier layer 13. At this time, the wetting layer 14 is also formed with the InAs quantum dots 15a.

Then, the In_{0.2}Ga_{0.8}As strain relaxation layer 16 is formed by the MBE to cover the sidewalls of the InAs quantum dots 15a. At this time, a thickness of the In_{0.2}Ga_{0.8}As strain relaxation layer 16 is made smaller than a height of the InAs quantum dots 15a.

Then, the top of the InAs quantum dots 15a is reevaporated using a flushing method while raising a temperature within a furnace for performing the MBE. Thereby, the height of the InAs quantum dots 15a is made equal to a thickness of the In_{0.2}Ga_{0.8}As strain relaxation layer 16. Through this step, the quantum dot layer 15 including the InAs quantum dots 15a and the In_{0.2}Ga_{0.8}As strain relaxation layer 16 covering the sidewall of the InAs quantum dots 15a is formed.

Then, the p-type In_{0.23}Ga_{0.77}As layer 17 (thickness: about 10 nm) having a P-type impurity concentration of about 5×10¹⁷ cm⁻³ is formed by the MBE over the quantum dot layer 15.

Then, the GaAs barrier layer 18 (thickness: about 23 nm) is formed by the MBE over the p-type In_{0.23}Ga_{0.77}As layer 17.

Here, the quantum dot layer 15, the p-type In_{0.23}Ga_{0.77}As layer 17 and the GaAs barrier layer 18 are further alternately laminated nine times to form the ten quantum dot layers 15. Thus, the quantum dot active layer 15b including from the GaAs barrier layer 13 to the uppermost GaAs barrier layer 18 is formed.

Then, the P-type Al_{0.4}Ga_{0.6}As cladding layer 19 is formed by the MBE over the quantum dot active layer 15b.

Then, the P-type GaAs contact layer 19a is formed by the MBE over the P-type Al_{0.4}Ga_{0.6}As cladding layer 19.

Thereby, the semiconductor light emitting element 11a is manufactured.

Next, the semiconductor light emitting element 11a is processed into the semiconductor light emitting laser device 11b as shown in FIG. 6.

The semiconductor light emitting laser device 11b has the following structure. Over an N—GaAs substrate 12a, the N-type Al_{0.4}Ga_{0.6}As cladding layer 12, the quantum dot active layer 15b, the P-type Al_{0.4}Ga_{0.6}As cladding layer 19 and the P-type GaAs contact layer 19a are sequentially laminated to form a ridge waveguide. Further, the ridge waveguide is buried with an insulating material 400, and a P-type electrode 19b and an N-type electrode 12b are formed over the upper and lower surfaces. Further, high-reflection films 401 or non-reflection films 402 are provided on end faces, if desired (in FIG. 6, the high-reflection films 401 are provided). Such a semiconductor light emitting laser device 11b is formed, for example, as follows.

First, a silicon dioxide (SiO₂) film (not shown) is formed to a thickness of about 300 nm over the semiconductor light emitting element 11a.

Then, a photolithography step is performed to form a ridge waveguide pattern over the SiO₂ film.

Then, a dry etching step is performed to transfer this pattern onto the P-type Al_{0.4}Ga_{0.6}As cladding layer 19 and to remove an unnecessary portion. Thereby, a ridge waveguide structure is formed.

Then, the ridge waveguide is buried with the insulating material 400 such as an ultraviolet curing resin.

Then, the P-type electrode 19b and N-type electrode 12b for current injection are formed over the upper and lower surfaces, respectively. The high-reflection films 401 or non-reflection films 402 are provided on the end faces, if desired (in FIG. 6, the high-reflection films 401 are provided).

Thus, the semiconductor light emitting laser device 11b is manufactured.

In the second embodiment, there is used a ridge waveguide structure in which the quantum dot active layer 15b is not etched. Even when using a high mesa waveguide structure in which the quantum dot active layer 15b is etched, the same effect can be obtained.

In the second embodiment, the number of laminated quantum dot layers 15 is 10. Further, the number thereof can be changed depending on the intended use of the semiconductor light emitting element 11a.

In addition, as for the layered structure, various shapes can be adopted in the same manner as in the first embodiment.

Next, a third embodiment will be described.

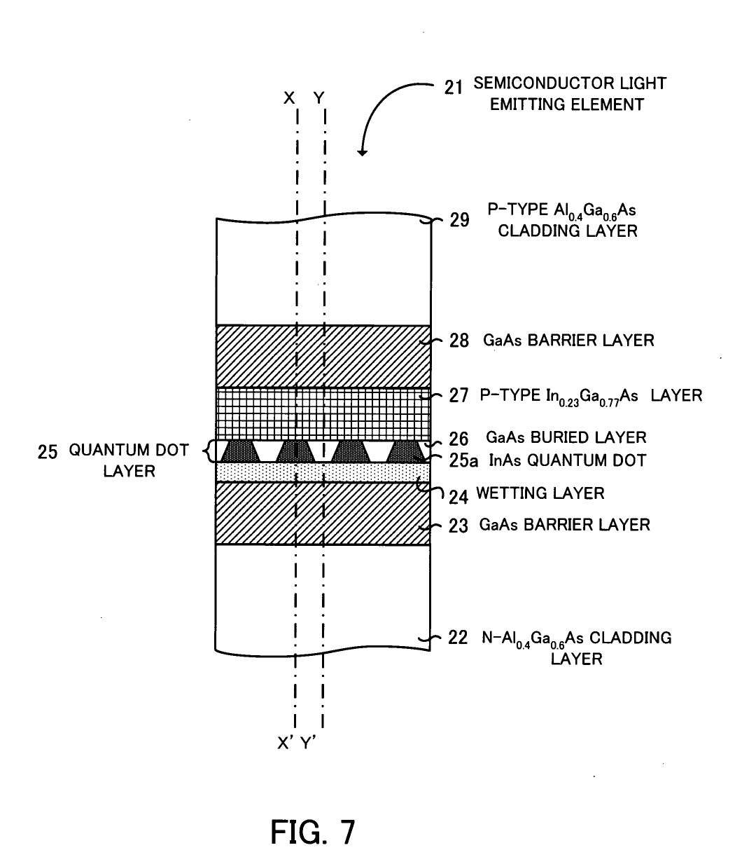

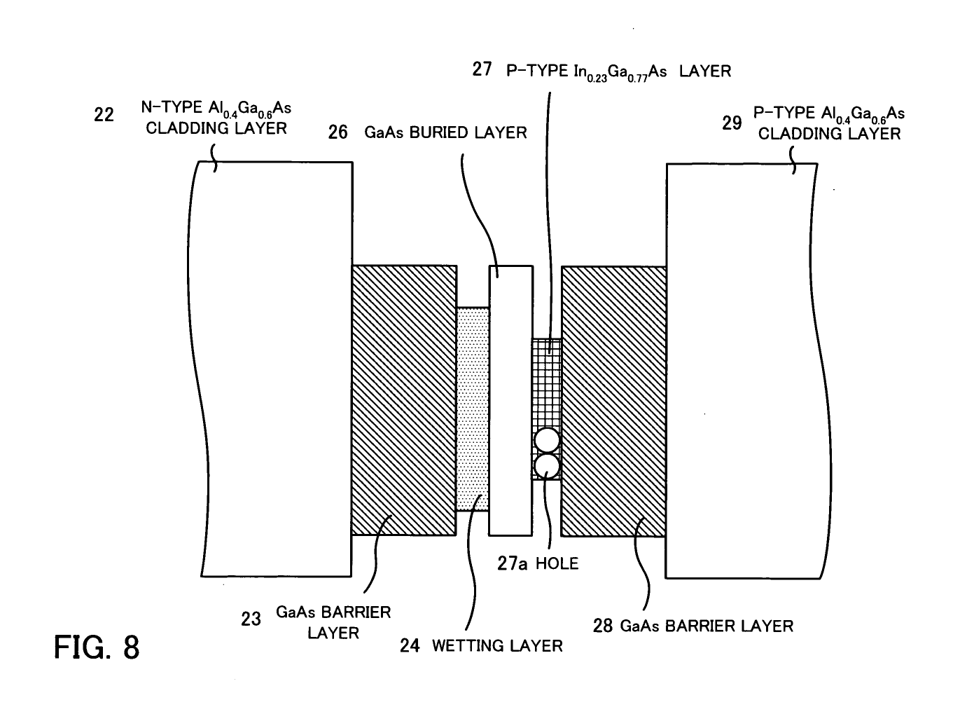

FIG. 7 is a schematic cross-sectional view of an essential part of a semiconductor light emitting element according to the third embodiment. FIG. 8 is a schematic view illustrating a band diagram of a cross-sectional structure taken along the dashed line Y-Y′ in FIG. 7. A schematic view illustrating a band diagram of a cross-sectional structure taken along the dashed line X-X′ in FIG. 7 may be referred to FIG. 3.

A semiconductor light emitting element 21 has a structure in which an N-type Al_{0.4}Ga_{0.6}As cladding layer 22, a GaAs barrier layer 23, a wetting layer 24, a quantum dot layer 25 having InAs quantum dots 25a and a GaAs buried layer 26 covering a sidewall of the InAs quantum dots 25a, a P-type In_{0.23}Ga_{0.77}As layer 27, a GaAs barrier layer 28 and a P-type Al_{0.4}Ga_{0.6}As cladding layer 29 are sequentially formed over the N-type GaAs (001) substrate (not shown). The GaAs buried layer 26 is formed instead of the In_{0.2}Ga_{0.8}As strain relaxation layer 16 in the semiconductor light emitting element 11 according to the first embodiment. Such a semiconductor light emitting element 21 is formed, for example, as follows.

First, the N-type Al_{0.4}Ga_{0.6}As cladding layer 22 (thickness: about 1.4 μm) is formed by the MBE over the N-type GaAs (001) substrate (not shown).

Then, the GaAs barrier layer 23 (thickness: about 33 nm) is formed by the NBE over the N-type Al_{0.4}Ga_{0.6}As cladding layer 22.

Then, the InAs quantum dots 25a are formed to have a surface density of about 4×10¹⁰ cm⁻² by the self-assemble method over the GaAs barrier layer 23. At this time, the wetting layer 24 is also formed with the InAs quantum dots 25a.

Then, the GaAs buried layer 26 is formed by the MBE to cover the sidewalls of the InAs quantum dots 25a. At this time, a thickness of the GaAs buried layer 26 is made smaller than a height of the InAs quantum dots 25a.

Then, the top of the InAs quantum dots 25a is reevaporated using a flushing method while raising a temperature within a furnace for performing the MYE. Thereby, the height of the InAs quantum dots 25a is made equal to a thickness of the GaAs buried layer 26. Through this step, the quantum dot layer 25 including the InAs quantum dots 25a and the GaAs buried layer 26 covering the sidewall of the InAs quantum dots 25a is formed.

Then, the p-type In_{0.23}Ga_{0.77}As layer 27 (thickness: about 10 nm) having a P-type impurity concentration of about 5×10¹⁷ cm⁻³ is formed by the MBE over the quantum dot layer 25.

Then, the GaAs barrier layer 28 (thickness: about 23 nm) is formed by the MBE over the p-type In_{0.23}Ga_{0.77}As layer 27.

Then, the P-type Al_{0.4}Ga_{0.6}As cladding layer 29 is formed by the MBE over the GaAs barrier layer 28.

Thus, the semiconductor light emitting element 21 is manufactured.

In the third embodiment, in the same manner as in the first embodiment, the InAs quantum dots 25a are not in contact with impurities. Accordingly, it becomes possible to form the InAs quantum dots 25a whose crystallinity is prevented from decreasing and whose quality is maintained. On the other hand, in the cross section taken along the dashed line Y-Y′, the p-type In_{0.23}Ga_{0.77}As layer 27 is sandwiched between the GaAs buried layer 26 and GaAs barrier layer 28 having a band gap larger than that of the layer 27 as shown in FIG. 8. Accordingly, the holes 27a generated in the layer 27 are prevented from flowing into the GaAs buried layer 26 and GaAs barrier layer 28. As a result, the holes 27a are caused to flow into the InAs quantum dots 25a, so that the injection efficiency into the InAs quantum dots 25a can be improved.

In the third embodiment, in the same manner as in the second embodiment, the quantum dot layer 25, the p-type In_{0.23}Ga_{0.77}As layer 27 and the GaAs barrier layer 28 are alternately laminated plural times. Thereby, the semiconductor light emitting element 21 can be manufactured.

In addition, as for the layered structure, various shapes can be adopted in the same manner as in the first and second embodiments.

Next, a fourth embodiment will be described.

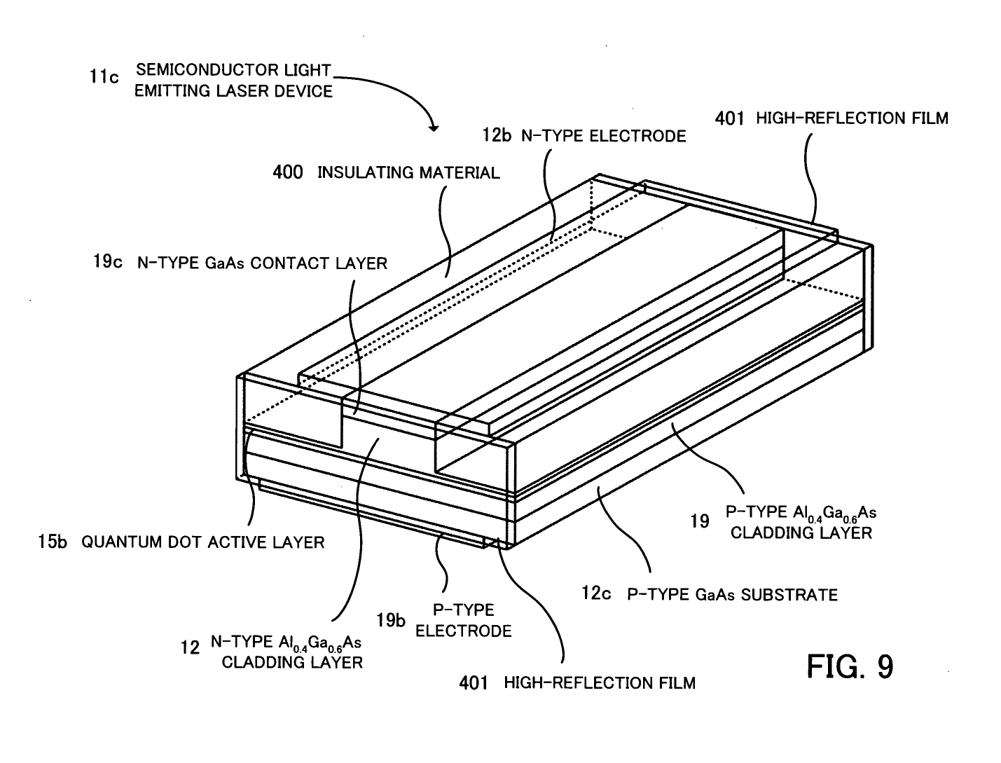

FIG. 9 is a schematic oblique view of a semiconductor light emitting laser device according to the fourth embodiment.

In the fourth embodiment, a P-type GaAs substrate 12c is used instead of the N-type GaAs substrate 12a in the semiconductor light emitting element 11a according to the second embodiment. At this time, conductivity of the layered structure other than that of the quantum dot active layer 15b is opposite to that of the second embodiment.

The semiconductor light emitting laser device 11c has the following structure. Over the P—GaAs substrate 12c, the P-type Al_{0.4}Ga_{0.6}As cladding layer 19, the quantum dot active layer 15b, the N-type Al_{0.4}Ga_{0.6}As cladding layer 12 and the N-type GaAs contact layer 19c are sequentially laminated to form a ridge waveguide. Further, the ridge waveguide is buried with the insulating material 400, and the N-type electrode 12b and the P-type electrode 19b are formed over the upper and lower surfaces. Further, the high-reflection films 401 or non-reflection films 402 are provided over the end faces, if desired (in FIG. 9, the high-reflection films 401 are provided).

Such a semiconductor light emitting laser device 11c can be manufactured by substituting the P-type GaAs substrate 12c for the N-type GaAs (001) substrate 12a, the P-type Al_{0.4}Ga_{0.6}As cladding layer 19 for the N-type Al_{0.4}Ga_{0.6}As cladding layer 12, the N-type Al_{0.4}Ga_{0.6}As cladding layer 12 for the P-type Al_{0.4}Ga_{0.6}As cladding layer 19, the N-type electrode 12b for the P-type electrode 19b, and the P-type electrode 19b for the N-type electrode 12b in the manufacture of the semiconductor light emitting element 11a according to the second embodiment.

According to the fourth embodiment, a PN junction area is reduced more than that of the second embodiment. As a result, a capacitance of the semiconductor light emitting laser device 11c is also reduced, so that a high-speed modulation operation is enabled.

In addition, as for the layered structure, various shapes can be adopted in the same manner as in the first and second embodiments.

Next, a fifth embodiment will be described.

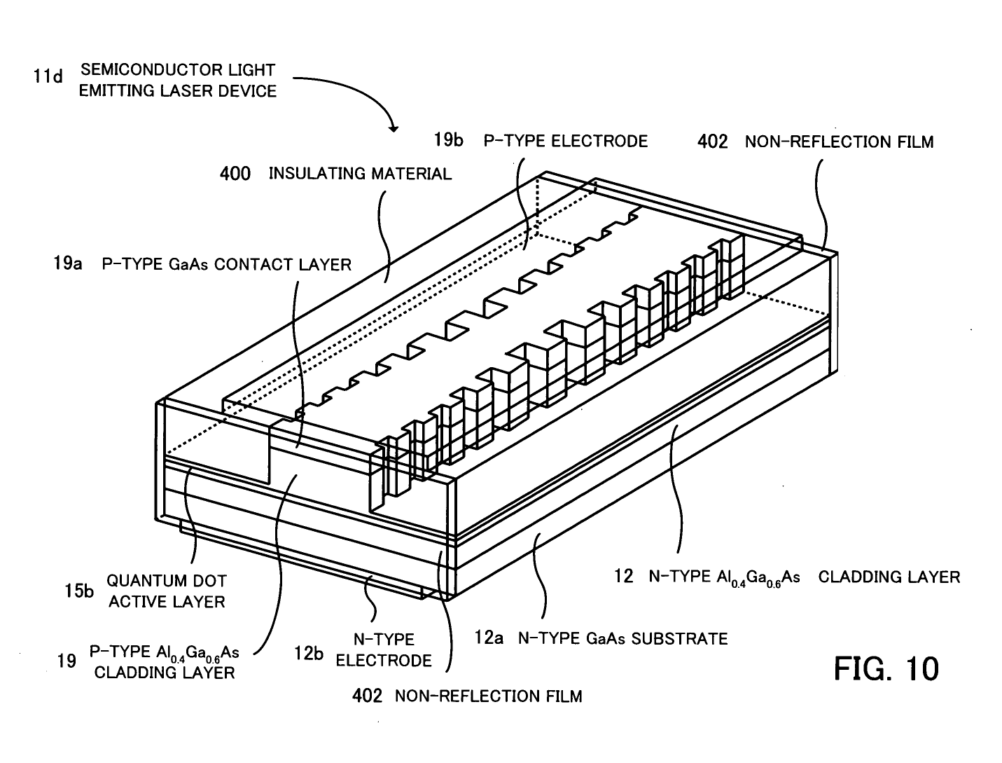

FIG. 10 is a schematic oblique view of a semiconductor light emitting laser device according to the fifth embodiment.

In the fifth embodiment, a layered structure of a semiconductor light emitting element is the same as that of the semiconductor light emitting element 11a according to the second embodiment. The semiconductor light emitting laser device according to the fifth embodiment is a laser device in which a diffraction grating is perpendicularly formed on the sidewall of the ridge waveguide in the semiconductor light emitting laser device 11b according to the second embodiment. That is, the semiconductor light emitting laser device according to the fifth embodiment is a vertical diffraction grating DFB (Distributed FeedBack) laser device.

A semiconductor light emitting laser device 11d has the following structure. Over the N-type GaAs substrate 12a, the N-type Al_{0.4}Ga_{0.6}As cladding layer 12, the quantum dot active layer 15b, the P-type Al_{0.4}Ga_{0.6}As cladding layer 19 and the P-type GaAs contact layer 19a are sequentially laminated to form a ridge waveguide. Over the sidewall of the ridge waveguide, a diffraction grating is vertically and periodically formed. Further, the ridge waveguide is buried with the insulating material 400, and the P-type electrode 19b and the N-type electrode 12b are formed over the upper and lower surfaces. Further, the high-reflection films 401 or non-reflection films 402 are provided over the end faces of the device 11d, if desired (in FIG. 10, the non-reflection films 402 are provided). Such a semiconductor light emitting laser device lid is formed, for example, as follows.

First, a silicon dioxide (SiO₂) film (not shown) is formed to a thickness of about 300 nm over the semiconductor light emitting element 11a.

Then, a photolithography step is performed to form a ridge waveguide pattern over the SiO₂ film.

Then, an electron beam exposure step is performed to form a diffraction grating and a ridge waveguide structure over the SiO₂ film.

Further, the ridge waveguide is buried with the insulating material 400 such as an ultraviolet curing resin, and the P-type electrode 19b and the N-type electrode 12b for current injection are formed over the upper and lower surfaces, respectively. Further, the high-reflection films 401 or non-reflection films 402 are provided over the end faces, if desired (in FIG. 10, the non-reflection films 402 are provided).

Thus, the semiconductor light emitting laser device 11d is manufactured.

According to the fifth embodiment, the diffraction grating is vertically and periodically formed over the sidewall of the ridge waveguide. As a result, the semiconductor light emitting laser device 11d can be used as a DFB laser in which among light having plural wavelengths, only light having a wavelength corresponding to this period is oscillated to cause an optical amplification action, so that single-mode light can be output.

In addition, as for the layered structure, various shapes can be used in the same manner as in the first and second embodiments.

Next, a sixth embodiment will be described.

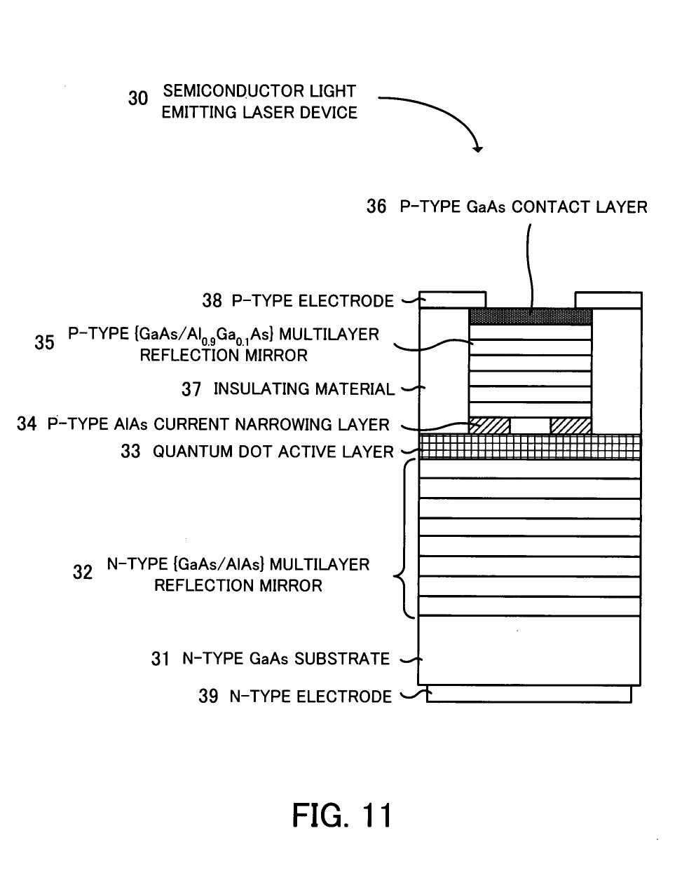

FIG. 11 is a schematic oblique view of a semiconductor light emitting laser device according to the sixth embodiment.

In the sixth embodiment, a layered structure of the quantum dot active layer 15b of the semiconductor light emitting element 11a according to the second embodiment is used for a quantum dot active layer 33 of the semiconductor light emitting laser device 30.

The device 30 has the following structure. An N-type {GaAs/aluminum arsenic (AlAs)} multilayer reflection mirror 32, the quantum dot active layer 33, a P-type AlAs current confinement layer 34, a P-type {GaAs/Al_{0.9}Ga_{0.1}As) multilayer reflection mirror 35, a P-type GaAs contact layer 36, an insulating material 37, a P-type electrode 38 and an N-type electrode 39 are sequentially formed over an N-type GaAs substrate 31. Such a semiconductor light emitting laser device 30 is formed, for example, as follows.

First, the N-type {GaAs/aluminum arsenic (AlAs)} multilayer reflection mirror 32 is formed by the MBE over the N-type GaAs substrate 31.

Then, the quantum dot active layer 33 having the same layered structure as that of the second embodiment is formed over the N-type {GaAs/aluminum arsenic (AlAs)} multilayer reflection mirror 32. At this time, in order that a loop of a standing wave is positioned at the center of the quantum dot active layer 33, an adjustment is performed by forming a GaAs layer (not shown) over and under the quantum dot active layer 33.

Then, the P-type AlAs current confinement layer 34 (not shown) is formed by the MBE over the quantum dot active layer 33.

Then, the P-type {GaAs/Al_{0.9}Ga_{0.1}As} multilayer reflection mirror 35 (not shown) is formed over the P-type AlAs current confinement layer 34 (not shown).

Then, the P-type GaAs contact layer 36 (not shown) is formed over the P-type {GaAs/Al_{0.9}Ga_{0.1}As} multilayer reflection mirror 35 (not shown).

Then, after the formation of the P-type GaAs contact layer 36 (not shown), a normal photolithography step is performed to form a mesa structure where the P-type AlAs current confinement layer 34, the P-type {GaAs/Al_{0.9}Ga_{0.1}As} multilayer reflection mirror 35, and the P-type GaAs contact layer 36 are exposed.

Then, after the formation of the mesa structure, AlAs is oxidized by a native oxidization method to form a current confinement structure.

Finally, the mesa structure is buried with the insulating material 37 such as an ultraviolet curing resin, and the P-type electrode 38 and the N-type electrode 39 for current injection are formed over the upper and lower surfaces of the device 30, respectively.

Thus, the semiconductor light emitting laser device 30 is manufactured.

For the layered structure of the quantum dot active layer 33 having the same structure as those of the first and second embodiments, various shapes can be adopted.

In the above-described embodiments, an InAs/AlGaAs compound semiconductor formed over an N-type GaAs substrate, and a GaInAsP compound semiconductor and AlGaInAs compound semiconductor formed over an InP substrate are used as materials for constituting the semiconductor light emitting elements. Further, it is clear that the same effect can be obtained also in a combination of other materials capable of constituting the semiconductor light emitting laser devices. Further, substrate conductivity can be formed not only over an N-type/P-type substrate but also over a high resistivity substrate. In the above embodiments, there is provided an example of forming the semiconductor light emitting laser device by one-time crystal growth and etching. Further, the present invention can be applied to the formation of the semiconductor light emitting laser device by a plurality of crystal growth processes including embedded growth.

The semiconductor light emitting element of the present invention comprises: a semiconductor substrate, a first conductivity-type cladding layer formed over the semiconductor substrate; a first barrier layer formed over the first conductivity-type cladding layer; a quantum dot layer formed over the first barrier layer, the quantum dot layer including the quantum dots having a band gap smaller than that of the first barrier layer and a buried layer having a band gap larger than that of the quantum dots, the buried layer covering a sidewall of the quantum dots; a P-type semiconductor layer formed over the quantum dot layer, the P-type semiconductor layer having a band gap smaller than that of the first barrier layer; a second barrier layer formed over the P-type semiconductor layer, the second barrier layer having a band gap larger than those of the quantum dots and of the P-type semiconductor layer; and a second conductivity-type cladding layer formed over the second barrier layer. As a result, holes generated in the P-type semiconductor layer are prevented from flowing into the second barrier layer or the buried layer. As a result, injection efficiency of the holes generated in the P-type semiconductor layer into quantum dots is improved, so that luminous efficiency can be improved.

Further, the method of manufacturing a semiconductor light emitting element of the present invention comprises the steps of: forming a first conductivity-type cladding layer over the semiconductor substrate; forming a first barrier layer over the first conductivity-type cladding layer; forming a quantum dot layer over the first barrier layer, the quantum dot layer including the quantum dots having a band gap smaller than that of the first barrier layer and a buried layer having a band gap larger than that of the quantum dots, the buried layer covering a sidewall of the quantum dots; forming a P-type semiconductor layer over the quantum dot layer, the P-type semiconductor layer having a band gap smaller than that of the first barrier layer; forming a second barrier layer over the P-type semiconductor layer, the second barrier layer having a band gap larger than those of the quantum dots and of the P-type semiconductor layer; and forming a second conductivity-type cladding layer over the second barrier layer. As a result, injection efficiency of the holes generated in the P-type semiconductor layer into quantum dots is improved, so that luminous efficiency can be improved.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor light emitting element having quantum dots, comprising:
a semiconductor substrate,
a first conductivity-type cladding layer formed over the semiconductor substrate;
a first barrier layer formed over the first conductivity-type cladding layer;
a quantum dot layer formed over the first barrier layer, the quantum dot layer including the quantum dots having a band gap smaller than that of the first barrier layer and a buried layer having a band gap larger than that of the quantum dots, the buried layer covering a sidewall of the quantum dots;
a P-type semiconductor layer formed over the quantum dot layer, the P-type semiconductor layer having a band gap smaller than those of the first barrier layer and of the buried layer;
a second barrier layer formed over the P-type semiconductor layer, the second barrier layer having a band gap larger than those of the quantum dots and of the P-type semiconductor layer; and
a second conductivity-type cladding layer formed over the second barrier layer.

2. The semiconductor light emitting element according to claim 1, wherein there are used gallium arsenic for the semiconductor substrate, gallium arsenic for the first and second barrier layers, and P-type indium gallium arsenic for the P-type semiconductor layer.

3. The semiconductor light emitting element according to claim 1, wherein a lattice constant of the buried layer is larger than that of the semiconductor substrate.

4. The semiconductor light emitting element according to claim 2, wherein an indium composition of the P-type semiconductor layer using P-type indium gallium arsenic is changed from 0.23 to 0.26 toward the quantum dot layer.

5. The semiconductor light emitting element according to claim 1, wherein indium gallium arsenic, aluminum gallium arsenic or gallium arsenic is used for the buried layer.

6. The semiconductor light emitting element according to claim 1, wherein there are used indium phosphorus for the semiconductor substrate, aluminum gallium indium arsenic or indium gallium arsenic phosphorus for the first and second barrier layers, and P-type aluminum gallium indium arsenic or p-type indium gallium arsenic phosphorus for the P-type semiconductor layer.

7. The semiconductor light emitting element according to claim 6, wherein the P-type semiconductor layer using P-type aluminum gallium indium arsenic and the semiconductor substrate using indium phosphorus are lattice-matched.

8. The semiconductor light emitting element according to claim 1, wherein the quantum dot layer, the P-type semiconductor layer and the second barrier layer are alternately laminated over the first barrier layer.

9. A method of manufacturing a semiconductor light emitting element having quantum dots, comprising the steps of:
forming a first conductivity-type cladding layer over the semiconductor substrate;
forming a first barrier layer over the first conductivity-type cladding layer;
forming a quantum dot layer over the first barrier layer, the quantum dot layer including the quantum dots having a band gap smaller than that of the first barrier layer and a buried layer having a band gap larger than that of the quantum dots, the buried layer covering a sidewall of the quantum dots;
forming a P-type semiconductor layer over the quantum dot layer, the P-type semiconductor layer having a band gap smaller than those of the first barrier layer and of the buried layer;
forming a second barrier layer over the P-type semiconductor layer, the second barrier layer having a band gap larger than those of the quantum dots and of the P-type semiconductor layer; and
forming a second conductivity-type cladding layer over the second barrier layer.

10. The method according to claim 9, wherein there are used gallium arsenic for the semiconductor substrate, gallium arsenic for the first and second barrier layers, and P-type indium gallium arsenic for the P-type semiconductor layer.

11. The method according to claim 9, wherein a lattice constant of the buried layer is larger than that of the semiconductor substrate.

12. The method according to claim 10, wherein an indium composition of the P-type semiconductor layer using P-type indium gallium arsenic is changed from 0.23 to 0.26 toward the quantum dots.

13. The method according to claim 9, wherein indium gallium arsenic, aluminum gallium arsenic or gallium arsenic is used for the buried layer.

14. The method according to claim 9, wherein there are used indium phosphorus for the semiconductor substrate, aluminum gallium indium arsenic or indium gallium arsenic phosphorus for the first and second barrier layers, and P-type aluminum gallium indium arsenic or p-type indium gallium arsenic phosphorus for the P-type semiconductor layer.

15. The method according to claim 14, wherein the P-type semiconductor layer using P-type aluminum gallium indium arsenic and the semiconductor substrate using indium phosphorus are lattice-matched.

16. The method according to claim 9, wherein the quantum dot layer, the P-type semiconductor layer and the second barrier layer are alternately laminated over the first barrier layer.

17. A semiconductor light emitting device, comprising:
a semiconductor light emitting element having quantum dots, the semiconductor light emitting element including:
a semiconductor substrate,
a first conductivity-type cladding layer formed over the semiconductor substrate;
a first barrier layer formed over the first conductivity-type cladding layer;
a quantum dot layer formed over the first barrier layer, the quantum dot layer including the quantum dots having a band gap smaller than that of the first barrier layer and a buried layer having a band gap larger than that of the quantum dots, the buried layer covering a sidewall of the quantum dots;
a P-type semiconductor layer formed over the quantum dot layer, the P-type semiconductor layer having a band gap smaller than those of the first barrier layer and of the buried layer;
a second barrier layer formed over the P-type semiconductor layer, the second barrier layer having a band gap larger than those of the quantum dots and of the P-type semiconductor layer; and
a second conductivity-type cladding layer formed over the second barrier layer.
